(19) United States
(12) Patent Application Publication
(10) Pub. No.: US 2009/0322433 A1
(43) Pub. Date: Dec. 31, 2009

(54) Method of Controlling Voltage-Controlled Oscillator

(76) Inventor: Chou-Jung TSAI, Kaohsiung City (TW)

Correspondence Address: SINORICA, LLC, 2275 Research Blvd., Suite 500, ROCKVILLE, MD, 20850, US

(21) Appl. No.: 12/203,253

(22) Filed: Sep. 3, 2008

(30) Foreign Application Priority Data
Jun. 30, 2008 (TW) 097124584

(51) Int. Cl. H03L 7/00

(52) U.S. Cl. 331/34

(57) ABSTRACT

The present invention relates to a method for controlling a voltage-controlled oscillator (VCO), which uses a control unit to produce a switching signal according to a counting signal for switching a plurality of current sources. The VCO receives the currents of the plurality of current sources and a reference current and produces an output frequency signal. Thereby, according to the present invention, the counting signal is used for controlling the currents of the plurality of current sources, and thus the frequency range of the output frequency signal can be controlled. The output frequency band of the VCO is broadened accordingly.

### FIELD OF THE INVENTION

The present invention relates generally to a voltage-controlled oscillator (VCO), and particularly to a method of controlling a voltage-controlled oscillator with a counting function.

### BACKGROUND OF THE INVENTION

The basic overall function of a phase-locked loop (PLL) is using an oscillation source with extremely low frequency variation as a reference to drive a variable frequency device in phase, which is named phase lock, with the oscillation source quickly and stably by means of feedback action of a close-loop control system. When the internal circuit reaches phase lock, it can be used as modulation/demodulation circuits in communication systems.

PLLs have been developed for a long time. They are still technical focus up to date. The main reasons are their wide applications and high potential. The development emphases include higher frequencies, enhanced stability, broader frequency band, and lower lock time.

In addition, voltage-controlled oscillators (VCOs) are set inside PLLs and can be applied to semiconductor apparatuses. The oscillation signals output by VCOs are supplied to circuits inside or outside the semiconductor apparatuses as timing signals.

VCOs have great influence on the oscillation accuracy and stability of the oscillation signals of PLLs. The characteristics of a VCO input voltage to output frequency varies depending on external interferences, such as semiconductor process variations, ambient temperatures, and variations in power supplies. Besides, in modem semiconductor apparatuses, a broad frequency oscillation range is required. In order to meet the requirements, the VCO's voltage-to-frequency gain has to be increased.

Accordingly, the present invention provides a novel method of controlling a VCO for broadening the output frequency band.

### SUMMARY

An objective of the present invention is to provide a method for controlling a voltage-controlled oscillator (VCO), which produces a counting signal according to the lock frequency of the lock signal for broadening the output frequency band of the VCO.

The VCO of the method for controlling a VCO according to the present invention comprises a conversion unit, a plurality of current sources, a plurality of switches, and a current-controlled oscillator. The control method includes that a control unit produces a switching signal for switching the plurality of switches according to a counting signal and thereby controls the total current output by the plurality of current sources, and the current-controlled oscillator produces an output frequency signal according to a received reference current converted by the conversion unit from a voltage control signal and to the total current output by the plurality of current sources.

### BRIEF DESCRIPTION OF THE DRAWINGS

FIG. 1 shows a block diagram of a phase-locked loop according to a preferred embodiment of the present invention;

FIG. 2 shows a block diagram according to a preferred embodiment of the present invention;

FIG. 3 shows a flowchart according to a preferred embodiment of the present invention; and

FIG. 4 shows a timing diagram according to a preferred embodiment of the present invention.

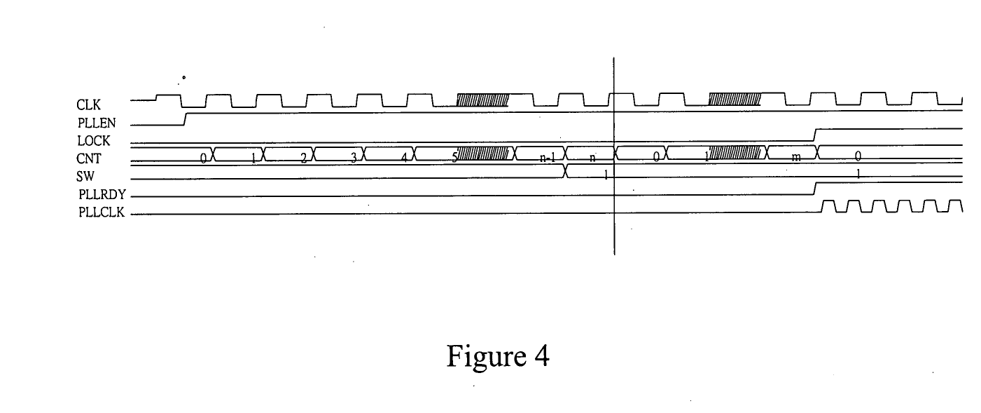

### DETAILED DESCRIPTION

In order to make the structure and characteristics as well as the effectiveness of the present invention to be further understood and recognized, the detailed description of the present invention is provided as follows along with preferred embodiments and accompanying figures.

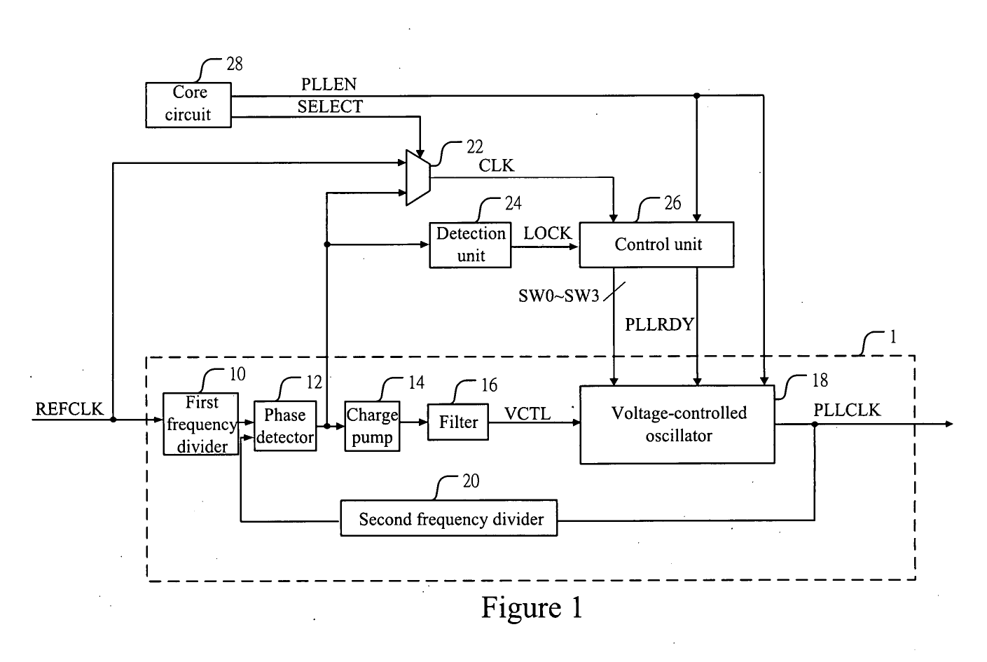

FIG. 1 shows a block diagram of a phase-locked loop according to a preferred embodiment of the present invention. As shown in the figure, the phase-locked loop (PLL) 1 according to the present invention comprises a first frequency divider 10, a phase frequency detector 12, a charge pump 14, a filter 16, a voltage-controlled oscillator 18, a second frequency divider 20, a multiplexer 22, a detection unit 24, and a control unit 26. The first frequency divider 10 receives a reference timing signal (REFCLK) and produces a first frequency-dividing signal. The phase frequency detector 12 detects the first frequency-dividing signal and a second frequency-dividing signal produced by the second frequency divider 20, compares the phase difference between the first and second frequency-dividing signals, and produces a phase detection signal. The charge pump 14 receives the phase detection signal and produces a charging signal. Because the charging signal produced by the charge pump 14 has, in addition to a DC component, which is proportional to the phase difference, an AC component. The high-frequency component in the AC component will cause the system unstable. Thereby, the filter 16 is used in the PLL for filtering the high-frequency component of the phase detection signal, and a voltage control signal (VCTL) is produced and transmitted to the voltage-controlled oscillator 18. The detection unit 24 detects the phase detection signal, produces a lock signal (LOCK) according to a lock frequency, and transmits the lock signal to the control unit 26. The multiplexer 22 receives the reference timing signal (REFCLK) or the phase detect signal, produces a timing signal (CLK) according to a select signal (SELECT) produced by a core circuit 28, and transmits the timing signal (CLK) to the control unit 26. The control unit 26 receives an enable signal (PLLEN) produced by the core circuit 28, and produces the switching signals (SW0 to SW3) and a ready signal (PLLRDY) to the voltage-controlled oscillator 18 according to the timing signal (CLK) and the lock signal (LOCK). After the voltage-controlled oscillator 18 confirms to have received the enable signal (PLLEN) and the ready signal (PLLRDY), it produces an output frequency signal (PLLCLK) according to the voltage control signal (VCTL) and the switching signal, and feedbacks the output frequency signal (PLLCLK) to the second frequency-dividing unit 20.

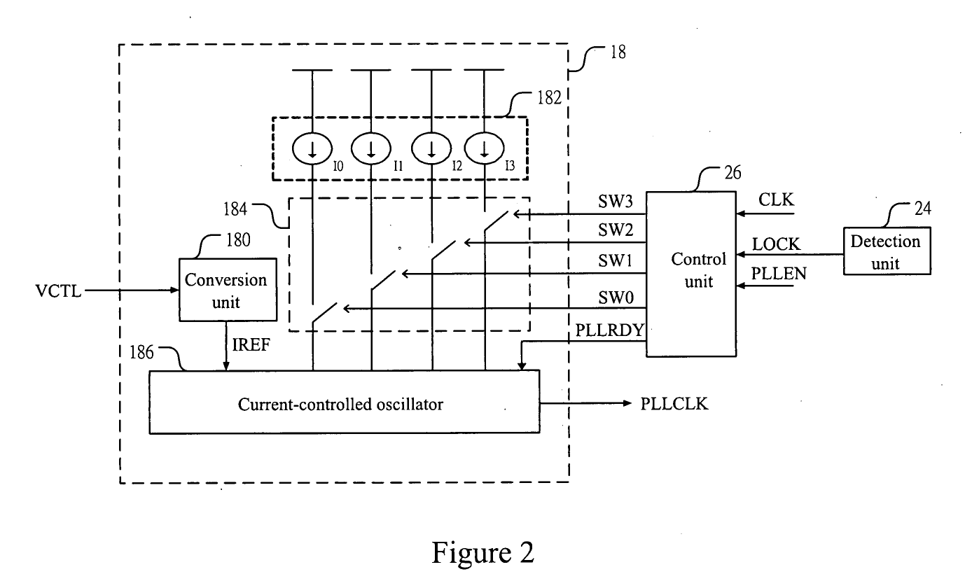

FIG. 2 shows a block diagram according to a preferred embodiment of the present invention. As shown in the figure, the VCO according to the present invention comprises a conversion unit 180, a plurality of current sources 182, a plurality of switches 184, and a current-controlled oscillator 186. The conversion unit 180 receives the voltage control signal, converts the voltage control signal and produces a reference current (IREF), and transmits to the current-controlled oscillator 186. The plurality of current sources 182 is coupled to the plurality of switches 184, respectively. The plurality of switches 184 is coupled to the control unit 26 and the current-controlled oscillator 186. The control unit 26 receives the enable signal (PLLEN), and controls the plurality of switches 184 according to the switching signals (SW0 to SW3) produced by a counting signal (CLK) and switches the plurality of current sources 182, wherein the counting signal (CLK) is the timing signal (CLK). Namely, according to the lock signal (LOCK) set by the detection unit 24, the control unit 26 controls the plurality of switches 184 with the counting signal (CLK), and produces the switching signals (SW0 to SW3) to switch the plurality of switches 184. The current-controlled oscillator 186 receives the reference current (IREF) and the currents produced by the plurality of current sources 182 corresponding to the turned on switches in the plurality of switches 184, sums up the currents, and converts the summed current to an output frequency signal (PLLCLK). According to the lock frequency, the control unit 26 can control the number of the plurality of current sources, which means controlling the current input to the current-controlled oscillator 186, and make the current-controlled oscillator 186 produce the output frequency signal (PLLCLK) with various frequencies. Thereby, according to the counting signal (CLK) and the lock signal (LOCK), the control unit 26 produces the switching signals (SW0 to SW3), and thus broadens the output frequency band of the VCO 18.

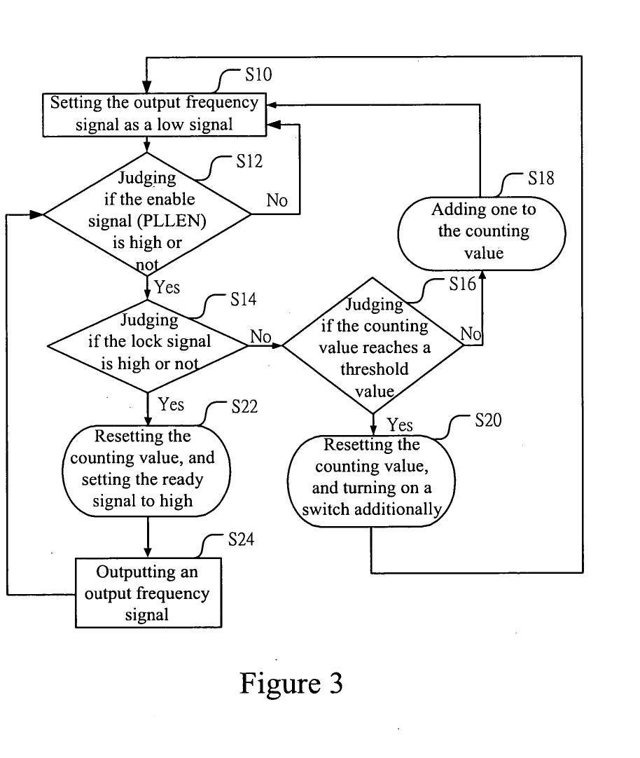

FIG. 3 shows a flowchart and a timing diagram according to a preferred embodiment of the present invention. As shown in the figures, the step S10 is executed first for setting the output frequency signal (PLLCLK) as a low signal. Then, the step S12 is executed for judging if the control unit 26 receives the enable signal (PLLEN) for action. When the enable signal (PLLEN) is low, it means that the control unit 26 has not received the enable signal (PLLEN), and the step S10 is re-executed for waiting the control unit 26 to receive the enable signal (PLLEN). When the enable signal (PLLEN) is high, it means that the control unit 26 has received the enable signal (PLLEN), and the step S14 is executed for judging if the lock signal (LOCK) is high or not. When the lock signal (LOCK) is low, the step S16 is executed for judging if the counting value reaches a threshold value. If not, the step S18 is executed for adding one to the counting value, and the step S10 is re-executed. If the counting value reaches the threshold value, the step S20 is executed for resetting the counting value, and turning on a switch additionally. Then, the step S10 is re-executed. If the lock signal (LOCK) is high, the step S22 is executed for resetting the counting value, and outputting the ready signal (PLLRDY) and the switching signals (SW0 to SW3) for switching the plurality of switches 184, and thereby the output current of the plurality of current sources 182 can be controlled. Afterwards, the step S24 is executed for producing an output frequency signal (PLLCLK).

To sum up, the method for controlling a VCO according to the present invention uses a control unit to produce a switching signal according to a counting signal for switching a plurality of current sources. The VCO receives the currents of the plurality of current sources and a reference current and produces an output frequency signal.

Accordingly, the present invention conforms to the legal requirements owing to its novelty, non-obviousness, and utility. However, the foregoing description is only a preferred embodiment of the present invention, not used to limit the scope and range of the present invention. Those equivalent changes or modifications made according to the shape, structure, feature, or spirit described in the claims of the present invention are included in the appended claims of the present invention.

1. A method for controlling a voltage-controlled oscillator (VCO), which comprises a plurality of current sources, the method for controlling switching the plurality of current sources for controlling the voltage-controlled oscillator, and comprising steps of:
producing a switching signal for switching the plurality of current sources according to a counting signal; and
converting the currents of the plurality of current sources and a reference current to produce an output frequency signal.

2. The method for controlling of claim 1, wherein the step of converting the currents of the plurality of current sources and a reference current to produce an output frequency signal outputs the output frequency signal with various frequencies according to the current of the plurality of current sources.

3. The method for controlling of claim 1, and further comprising a step of converting a voltage control signal to produce the reference current.

4. The method for controlling of claim 1, and further comprising a step of producing the output frequency signal according to a ready signal.

5. The method for controlling of claim 1, and further comprising a step of enabling a control unit, which produces the switching signal according to the counting signal.

6. The method for controlling of claim 1, and further comprising a step of transmitting the currents of the plurality of current sources and the reference current to a current-controlled oscillator.

7. The method for controlling of claim 1, wherein the step of producing a switching signal for switching the plurality of current sources according to a counting signal further comprises a step of producing the counting signal according to a lock signal.

8. The method for controlling of claim 7, wherein the step of producing the counting signal according to a lock signal produces the lock signal by detecting a phase-locked loop (PLL).

9. The method for controlling of claim 1, and applied to a phase-locked loop (PLL).
